(19) United States
(12) Patent Application Publication
(10) Pub. No.: US 2007/0117265 A1
(43) Pub. Date: May 24, 2007

(54) Semiconductor Device with Improved Stud Bump

(75) Inventor: Mutsumi Masumoto, Beppu-shi Oita (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/559,995

(22) Filed: Nov. 15, 2006

(30) Foreign Application Priority Data
Nov. 18, 2005 (JP) 2005-334420

(51) Int. Cl. H01L 21/00; H01L 23/02

(52) U.S. Cl. 438/108; 257/678

(57) ABSTRACT

The objective of this invention is to provide a type of semiconductor device enabling highly reliable flip chip connection. Semiconductor chip for flip chip assembly has gold stud bumps on a principal surface having a semiconductor integrated circuit formed on it, and the gold stud bumps contain silver (Ag). It is preferred that the silver content be 17%±2% by weight. The gold stud bumps are connected via solder bumps to Cu electrodes on substrate. Because silver is contained in gold stud bumps, it is possible to suppress the generation of voids and cracks in the joint between gold stud bumps and Cu electrodes.

### BACKGROUND OF THE INVENTION

The present invention pertains to a type of semiconductor device with flip chip assembly. In particular, the present invention pertains to a type of stud bump formed on the semiconductor chip.

The popularization of cell phones, notebook personal computers, and other small electronic devices has been accompanied by a high demand for reducing the size and pitch of the semiconductor chips carried in them. The flip chip assembly for connecting a bare chip on substrate is one of the technologies for assembling semiconductor chips with a higher degree of integration and smaller pitches. The flip chip assembly is for connection of the bump electrodes formed on the principal surface, as the surface of the semiconductor chip with the integrated circuit, to the electrodes or lands on the substrate facing them. Flip chip connection is adopted to substitute for the method of connecting semiconductor chip electrodes to the substrate by means of wire bonding.

The following methods may be adopted in flip chip connection: in one, the bare chip with bumps formed on it is pressed and joined to a substrate laminated with an anisotropic electroconductive film beforehand; in another method, the gold stud bumps on the bare chip are connected to the substrate electrodes by means of heat and pressure or ultrasonic wave vibration; in yet another method, the solder bumps on the bare chip are reflow connected to the substrate electrodes. Also, stress is concentrated at the gold stud bumps or solder bumps in flip chip connection. In order to prevent breakage of the joint, a method has been proposed in which a liquid underfilling resin is injected between the bare chip and the substrate to increase the connection strength.

Patent Reference 1¹ disclosed a type of semiconductor integrated circuit device manufactured by Texas Instruments Corp. and its assembly method. As shown in FIG. 6, in this method of assembling integrated circuit (IC) device 100 of the BGA (ball grid array) or LGA (land grid array) type, gold bumps 106 are formed on chip contact pads 105 with an interval of 100 μm or less as their inter-center distance, and the flip chip is attached to thin film plastic substrate 101. The stability of over-molded package 109 is realized due to the attachment of solder balls on its outer side, and non-electroconductive polymer adhesive 110 used to underfill the bumps acts to reinforce the rigidity of the package.
Japanese Kokai Patent Application No. 2002-170901

The material for the stud bumps in the prior art can be a gold alloy containing about 1% palladium. When the stud bumps are connected by solder to the Cu electrodes on the substrate, for other than the Au/Sn eutectic connection, plural voids and cracks are generated at the interface between solder and gold and the interface between solder and copper, and the strength of the flip chip connection is reduced. This is a problem to be addressed.

FIG. 7 is a photographic image of the cross section illustrating the state of the bump electrode joints when the device is placed in an oven at 150° C. for 500 h or 1000 h. 200 represents a stud bump; 210 represents solder; and 220 represents a Cu electrode. FIGS. 8A-8C are enlarged photographic images of the interface between the copper electrode and solder. FIGS. 9A-9C are enlarged photographic images of the interface between the stud bump and solder shown in FIG. 7.

As shown in FIG. 8B, voids 230 (the portions surrounded by circles) are generated at the interface after 500 h. After 1000 h, the voids have increased over time.

As shown in FIG. 9B, after 500 h, voids 230 are generated in the interior of Au/Sn, at the interface between Au and AuSn₂ and at the interface between Au and Au₅Al₂. On the other hand, after 1000 h, due to the diffusion of Au, the Au portion has almost entirely disappeared, and due to the generation of voids 230 at the interface between AuSn₂ and Au₅Al₂, cracks 240 develop, and corrosion 250 is observed in a portion.

### SUMMARY OF THE INVENTION

The objective of the present invention is to solve the aforementioned problems of the prior art by providing a type of semiconductor chip and semiconductor device employing flip chip connections that are highly reliable.

The present invention provides a type of semiconductor chip characterized by the fact that the semiconductor chip for flip chip assembly has plural gold stud bumps on the principal surface where a semiconductor integrated circuit is formed, and said gold stud bumps contain silver (Ag). It is preferred that the content of silver be 17%±2% with respect to gold. There is no specific restriction on the shape of the gold stud bumps. For example, they can be formed as protrusions on the principal surface of the semiconductor chip. The gold stud bumps are formed on the electrode pads formed on the principal surface of the semiconductor chip.

The semiconductor device of the present invention includes said semiconductor chip and a substrate with said semiconductor chip flip assembled on it. The plural gold stud bumps of the semiconductor chip are connected by solder to the plural corresponding electroconductive regions on the substrate. The solder is preferably free of lead, and in the form of a tin alloy containing silver. In addition, the tin alloy may contain Bi, Cu, In, etc. The plural electroconductive regions consist of wiring or electrodes of copper or copper alloy formed on the substrate by patterning. When the gold stud bumps on the semiconductor chip are connected to the electroconductive regions, ultrasonic vibration or heat and pressure can be applied. The substrate can be made of polyimide, glass epoxy resin, etc. There is no specific restriction on its material and configuration. Also, said plural electroconductive regions are formed on the first surface of the substrate, and plural external electrodes that are electrically connected to said plural electroconductive regions are formed on the second surface facing said first surface. As a result, a BGA or LGA package is formed. In addition, an underfill can be introduced between the semiconductor chip and the substrate.

### BRIEF DESCRIPTION OF THE DRAWINGS

FIG. 1 is a cross section illustrating the constitution of the semiconductor device in an application example of the present invention.

FIG. 2 illustrates the connection state of the gold stud bump electrodes with flip chip connection in the present invention application example. FIG. 2(a) is a cross-sectional photographic image illustrating the state when it is placed in an oven at 150° C., and FIG. 2(b) is a schematic diagram illustrating the connection state.

FIG. 3A is a cross-sectional photographic image illustrating the state of a joint between a Cu electrode and solder in the initial state.

FIG. 3B is a cross-sectional photographic image illustrating the state of a joint between a Cu electrode and solder after 500 h.

FIG. 3C is a cross-sectional photographic image illustrating the state of a joint between a Cu electrode and solder after 1000 h.

FIG. 4A is a cross-sectional photographic image illustrating the state of a joint between a the gold stud bump electrode and solder in the initial state.

FIG. 4B is a cross-sectional photographic image illustrating the state of a joint between a the gold stud bump electrode and solder after 500 h.

FIG. 4C is a cross-sectional photographic image illustrating the state of a joint between a the gold stud bump electrode and solder after 1000 h.

FIG. 5 is a graph illustrating the resistance when the gold stud bump electrodes of the present application example are used, as compared with that when conventional electrodes are used.

FIG. 6 is a cross-sectional photographic image of a semiconductor device with flip chip connection in the prior art.

FIG. 7 is a cross-sectional photographic image illustrating the connection state between the gold stud bump electrodes in flip chip connection in the prior art.

FIG. 8A is a cross-sectional photographic image illustrating the connection state between a Cu electrode and solder in the initial state.

FIG. 8B is a cross-sectional photographic image illustrating the state of a joint between a Cu electrode and solder after 500 h.

FIG. 8C is a cross-sectional photographic image illustrating the state of a joint between a Cu electrode and solder after 1000 h.

FIG. 9A is a cross-sectional photographic image illustrating the state of a joint between a gold stud bump electrode and solder in the initial state.

FIG. 9B is a cross-sectional photographic image illustrating the state of a joint between a gold stud bump electrode and solder after 500 h.

FIG. 9C is a cross-sectional photographic image illustrating the state of a joint between a gold stud bump electrode and solder after 1000 h.

### REFERENCE NUMERALS AND SYMBOLS AS SHOWN IN THE DRAWINGS

In the figures, 1 represents a semiconductor device, 10 represents a semiconductor chip, 12 represents a principal surface, 14 represents an electrode pad, 16 represents a gold stud bump, 20 represents a substrate, 22 represents a Cu electrode, 24 represents a solder bump, 26 represents internal wiring, 28 represents an external electrode, 30 represents an underfilling, resin, 32 represents a solder ball.

### DETAILED DESCRIPTION OF THE EMBODIMENTS

The present invention provides a type of semiconductor device characterized by the fact that by including silver in the gold stud bumps on the semiconductor chip, the generation of voids and cracks is suppressed at the interface between the stud bumps and solder in the flip chip connection, the joint strength is high, and the reliability is excellent.

In the following, a preferred embodiment of the present invention will be explained with reference to figures.

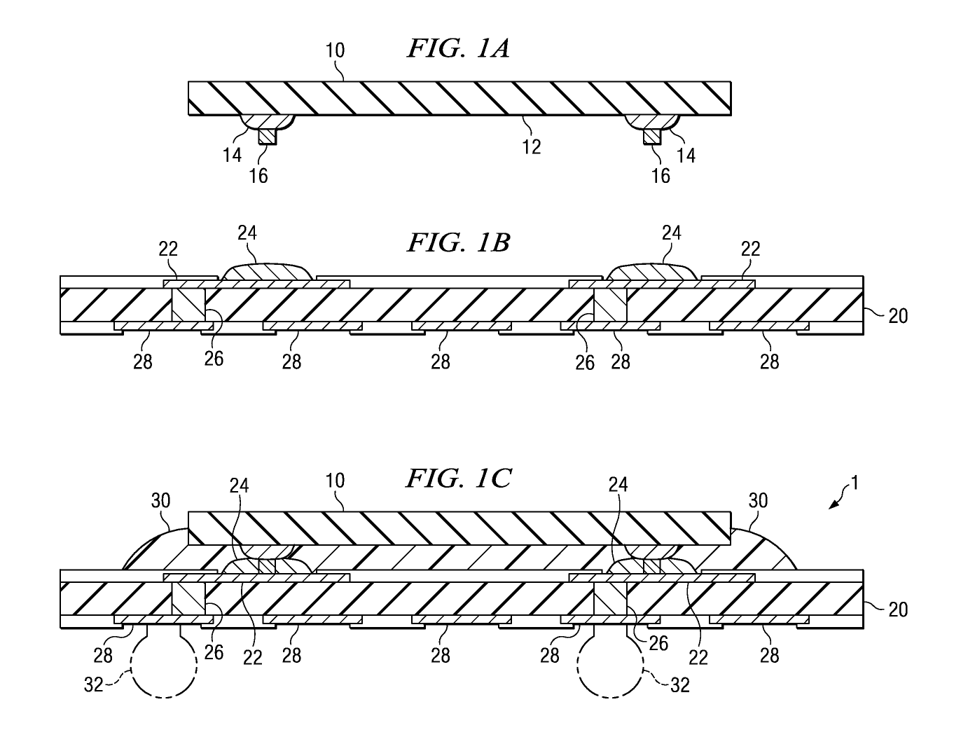

FIG. 1 is a cross section illustrating the constitution of the semiconductor device in an application example of the present invention. Said semiconductor device 1 has semiconductor chip 10 and substrate 20 for flip chip assembly of semiconductor chip 10 on it. Plural electrode pads 14 made of aluminum or aluminum alloy or the like are formed on principal surface 12 where the integrated circuit of semiconductor chip 10 is formed. Gold stud bumps 16 are formed on electrode pads 14. There is no specific restriction on the shape of the gold stud bumps. For example, semispherical, conical or rectangular shapes can be adopted. It is preferred that the gold stud bumps 16 have a height of 5 μm or greater from principal surface 12, and they are set with a pitch of 10 μm or greater.

Substrate 20 can be a laminated substrate, for example. Patterned electrodes 22 made of Cu or the like are formed on its upper surface. Solder bumps 24 are formed on said electrodes 22. Said solder bumps 24 are set at positions corresponding to electrode pads 14 or gold stud bumps 16 on semiconductor chip 10. Said solder bumps 24 are preferably made of a material free of lead, such as a tin alloy containing silver. The tin alloy can also contain copper, indium, bismuth, etc. Said electrodes 22 are connected via internal wiring 26 of substrate 20 to external electrodes 28 formed on the inner surface of the substrate. Electrodes 28 can be connected to solder balls 32 for BGA or CSP.

Said gold stud bumps 16 of semiconductor chip 10 are connected to solder bumps 32 of substrate 20, and gold stud bumps 16 and solder bumps 24 are joined to each other by means of solder flow. Because the joint between gold stud bumps 16 and solder bumps 24 is brittle, underfilling resin 30 for reinforcing them can be injected into the gap between principal surface 12 of semiconductor chip 10 on substrate 20.

A characteristic feature of the present invention is that silver (Ag) is contained in gold stud bumps 16. It is preferred that gold stud bumps 16 contain 17±2% of silver, and 0.01% or less of additives and impurities. It is well known that the stud bumps can be formed by using a well known wire bonding device or a dedicated stud bump bonder to form balls from gold wire, followed by cutting of the tip portions to form bumps. In this application example, gold wires containing silver are prepared to form gold stud bumps 16 on the electrode pads of the semiconductor chip by means of wire bonding. The gold wires containing silver used in this case have the following characteristics: a wire diameter of about 18 μm, a weight in the range of 0.77-0.96 (mg/200 mm), a breaking strength of 106 (mN), and an elongation of 0.5 (%) or more.

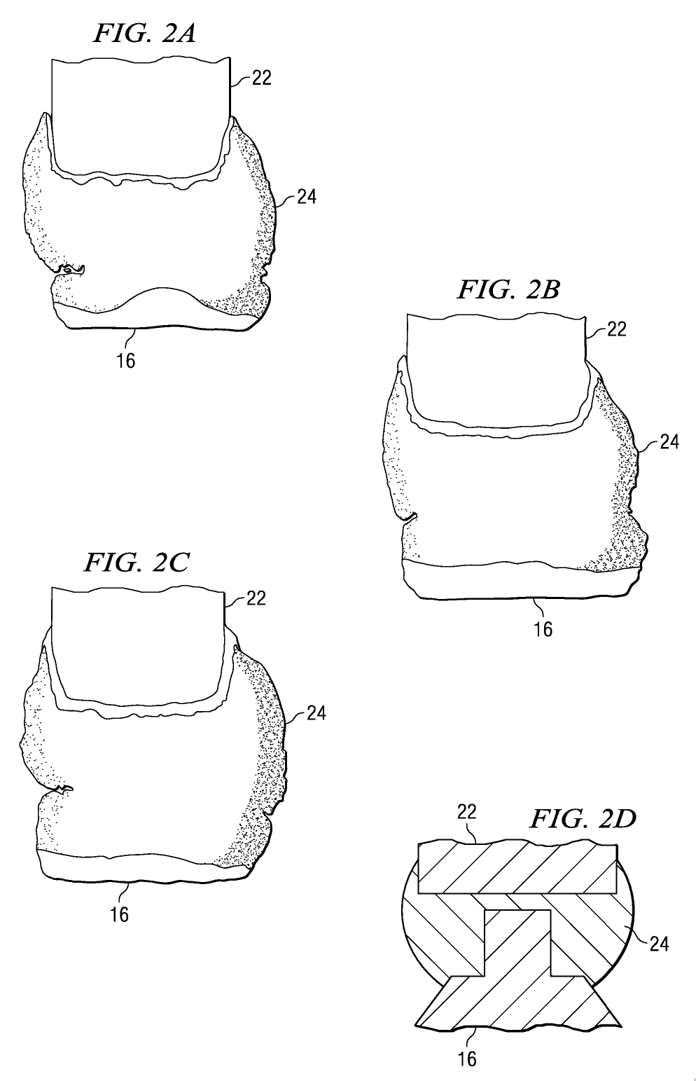

FIG. 2A is a cross-sectional photographic image illustrating the state of a joint between gold stud bumps 16 and Cu electrodes 22 when semiconductor device 1 with said constitution is placed in an oven at 150° C. without the application of a bias voltage to it. FIG. 2b is a schematic diagram illustrating the state of a joint between gold stud bumps 16 and Cu solder bumps 24. From left to right, the cross-sectional photographic images respectively indicate the joint state initially, after 500 h, and after 1000 h.

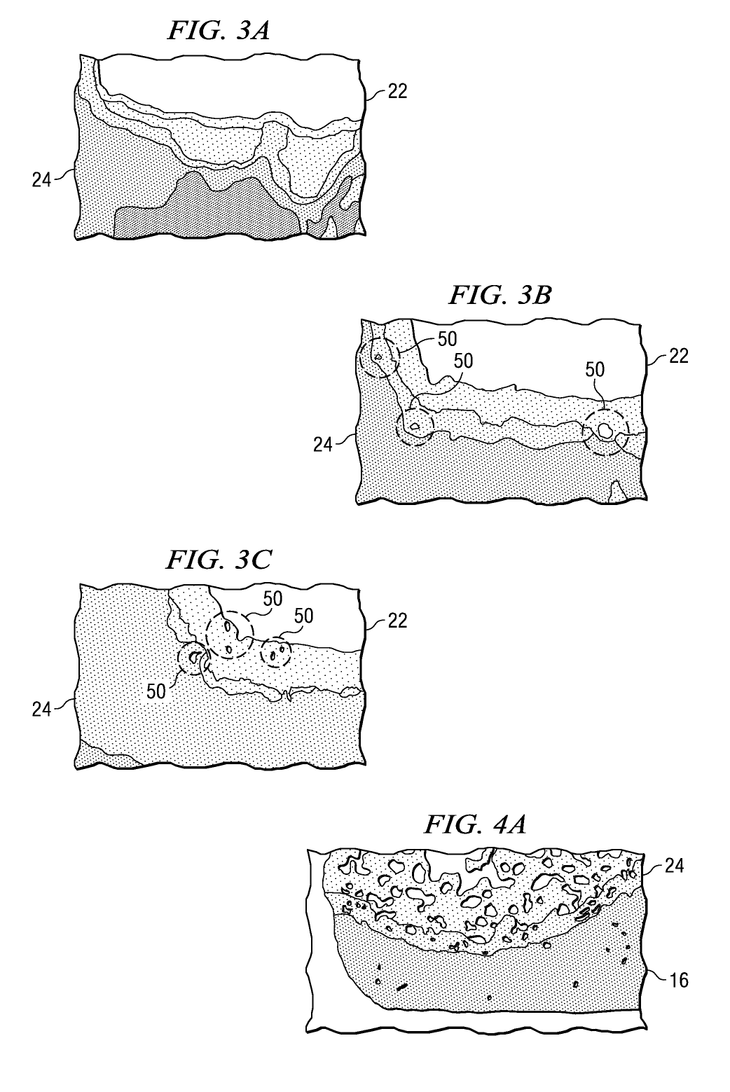

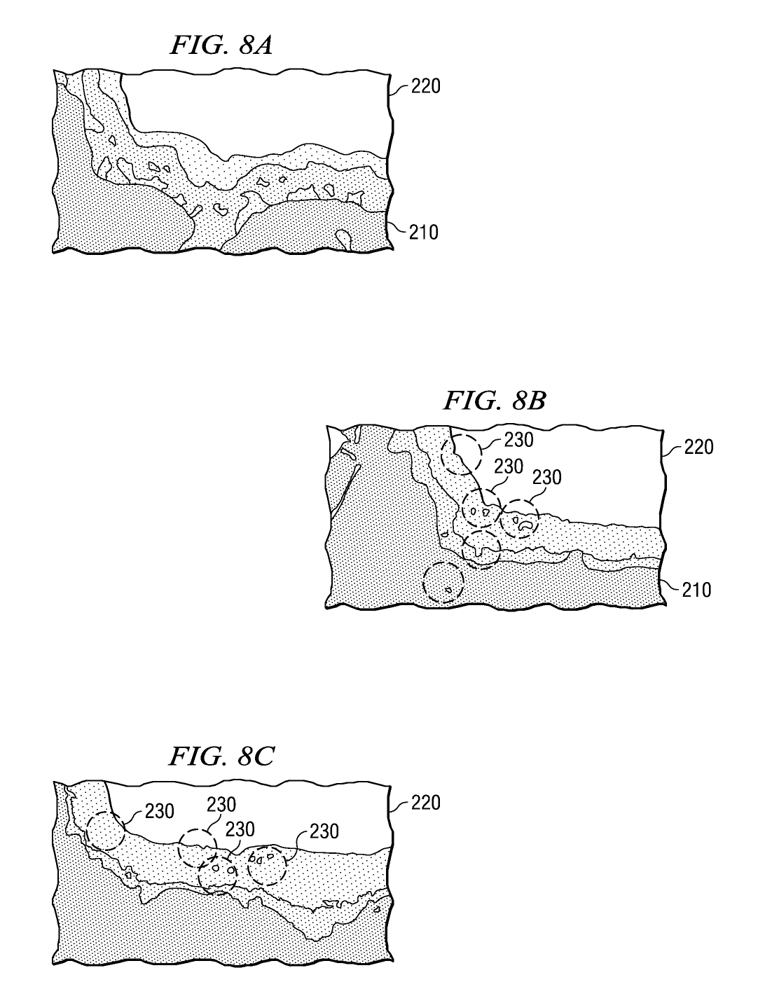

FIGS. 3A-3C are enlarged photographic images of FIG. 2 illustrating the state of a joint between the Cu electrodes and solder. They are BEI (composite images) with a magnification of 4000×. In the initial state, no voids have been generated. Then after 500 h, plural voids 50 (at sites indicated by circles) have been generated, as shown in FIG. 3B. However, compared with the conventional stud bumps shown in FIGS. 8A-8C, the generation frequency is much lower.

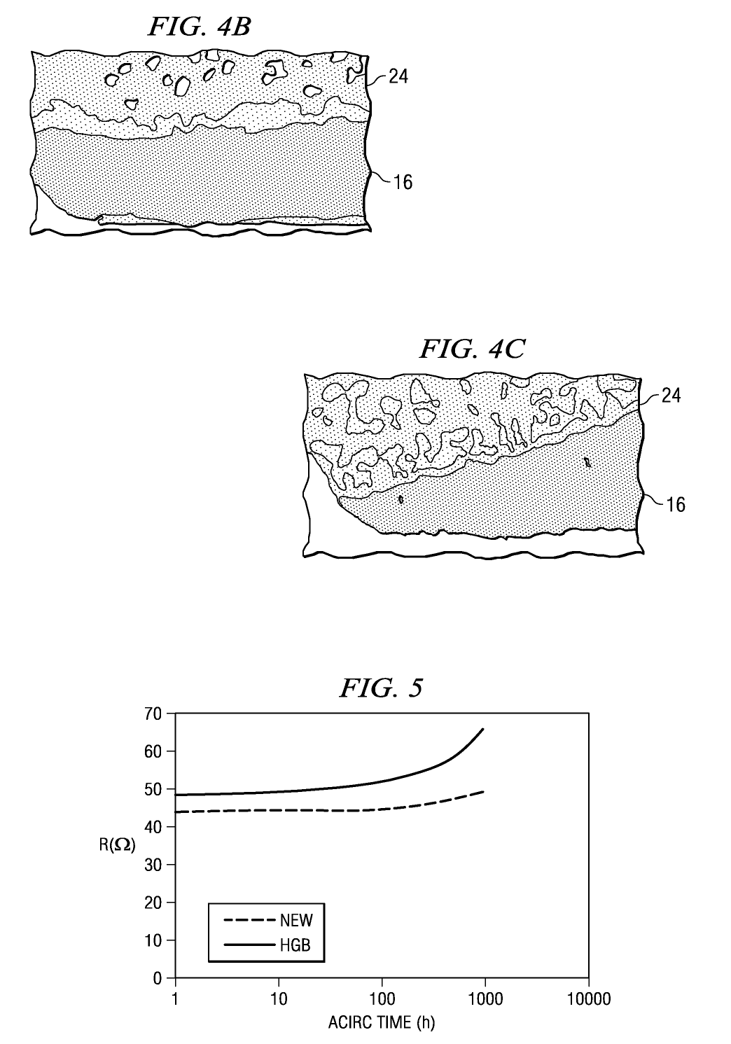

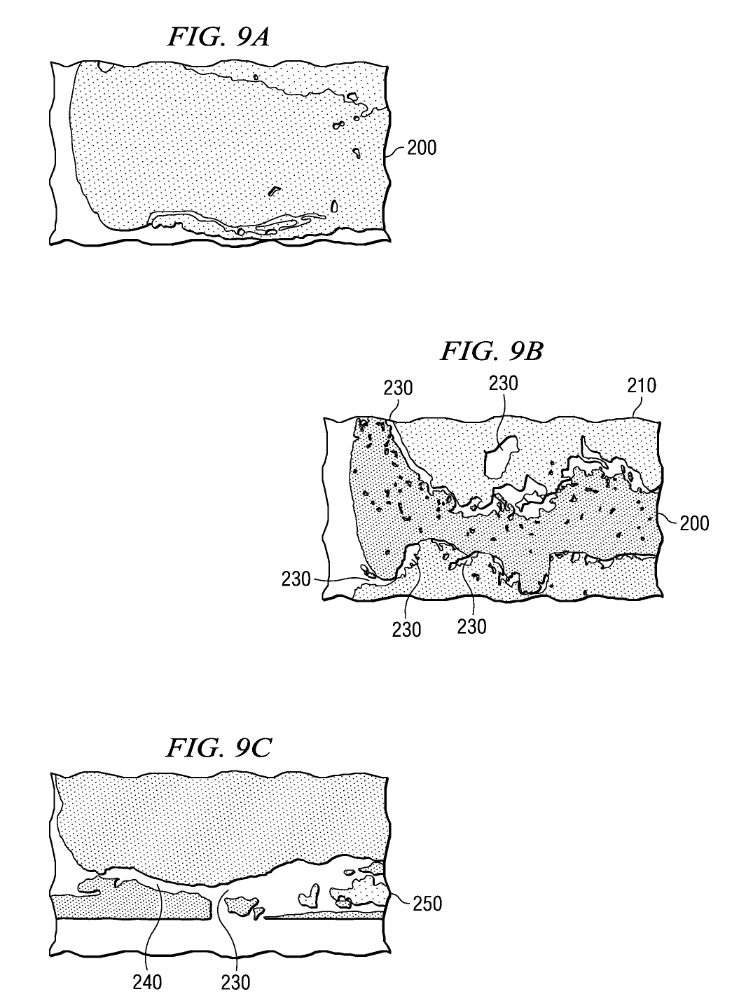

FIGS. 4A-4C are enlarged photographic images of FIG. 2 illustrating the state of a joint between the gold stud bumps and solder. As can be seen from these photographic images, compared with the conventional gold stud bumps shown in FIGS. 9A-9C, few voids or cracks are generated at the interface between the gold and solder.

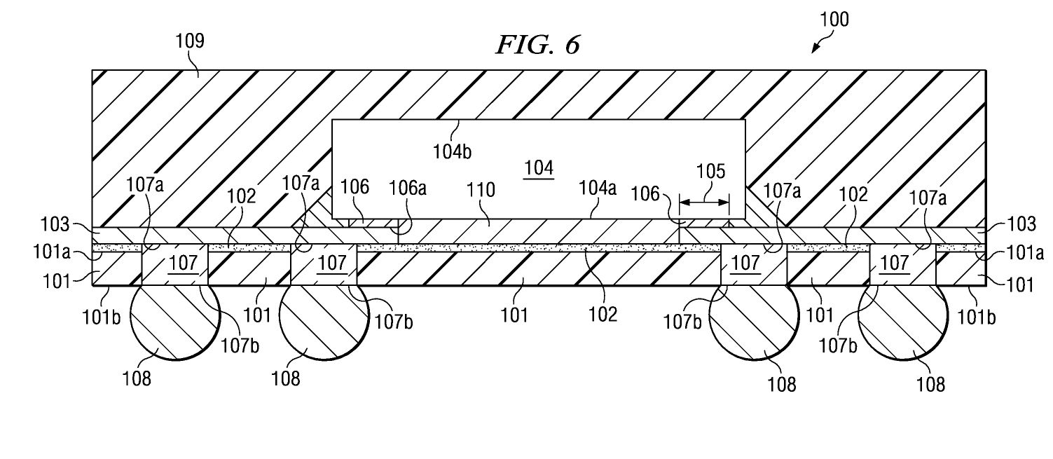

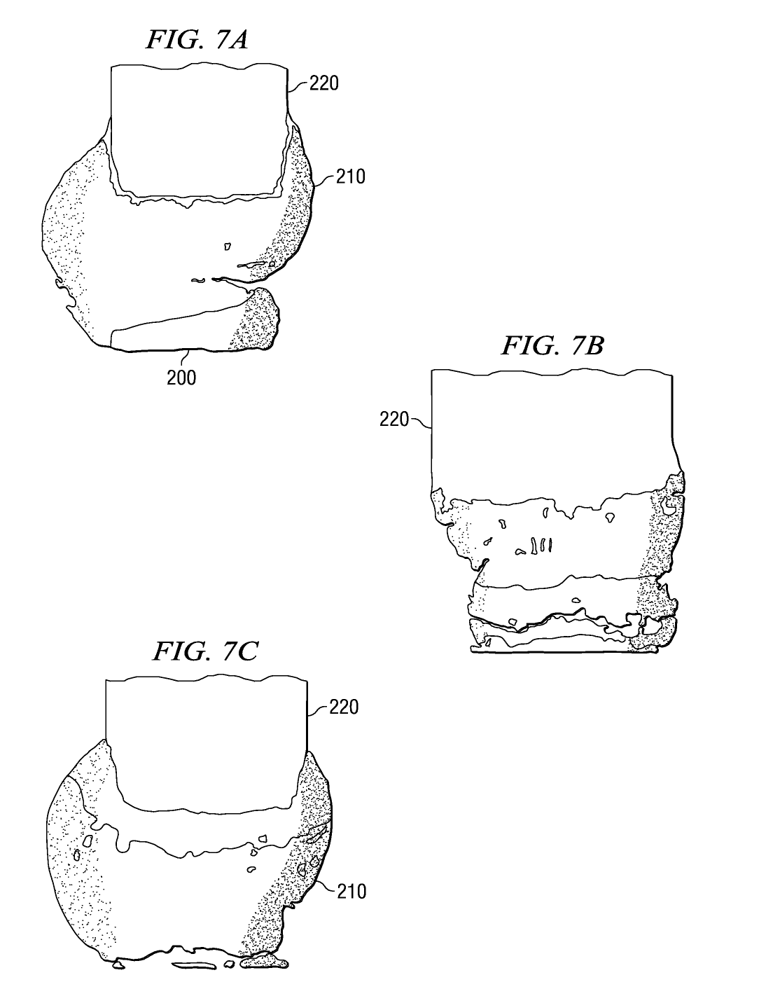

FIG. 5 is a graph illustrating the resistance when the gold stud bumps in the present application example are used (the curve labeled New) and the resistance when the conventional stud bumps are used (the curve labeled HBG). As can be seen clearly from the graph, for the conventional stud bumps the resistance starts rising after about 500 h, and the resistance rises by about 30% after about 1000 h. It is believed that multiple voids and cracks are generated at the interface between the bump and solder. On the other hand, for the gold stud bumps containing silver in the present application example, there is still only a minimal rise in the resistance even after 1000 h, and the generation of voids and cracks is suppressed.

In the following, a preferred embodiment of the present invention will be explained in more detail. However, the present invention is not limited to the specific embodiment. Various modifications and changes can be made as long as the gist of the present invention described in the claims is observed.

In said application example, an example of the package of formation of the solder balls is shown. However, this is merely an example, and other packages, such as CSP, LGA, can also be adopted. In addition, appropriate selections can be made regarding the shape, size and pitch of the gold stud bump electrodes corresponding to specific purposes and applications.

The present invention can be adopted in various electronic parts utilizing flip chip connection, especially semiconductors, assembly substrates, etc., that need to be small and very thin.

What is claimed is:

1. A semiconductor device comprising:
a semiconductor chip with gold stud bumps on a principal surface where a semiconductor integrated circuit is formed, and said gold stud bumps contain silver (Ag).

2. The semiconductor device described in claim 1, in which the content of silver is 17%±2% with respect to gold.

3. The semiconductor device described in claim 1, in which the gold stud bumps are formed on electrode pads formed on the principal surface of the semiconductor chip.

4. The semiconductor device described in claim 1, further comprising a substrate on which the semiconductor chip is assembled in a flip-chip fashion.

5. The semiconductor device described in claim 4, in which the gold stud bumps on the semiconductor chip are connected by solder to corresponding conductive regions on the substrate.

6. The semiconductor device described in claim 5, in which said solder is free of lead.

7. The semiconductor device described in claim 4, in which said solder is a tin alloy containing silver.

8. The semiconductor device described in claim 5, in which said conductive regions have patterns of copper or copper alloy.

9. The semiconductor device described in claim 4, in which said conductive regions are formed on the first surface of the substrate, and electrodes are formed on the second surface opposite to the first surface and are electrically connected to said conductive regions.

10. The semiconductor device described in claim 4, further comprising an underfilling resin filled between the principal surface of the semiconductor chip and the first surface of the substrate.
